(19) United States
(12) Patent Application Publication
(10) Pub. No.: US 2008/0107208 A1
(43) Pub. Date: May 8, 2008

(54) Mode switching method, mode switching program, and broadcast receiving terminal

(76) Inventors: Masaharu Kudou, Kanagawa (JP); Masato Takemoto, Tokyo (JP); Shinji Nakamoto, Kanagawa (JP); Kazuyuki Tanaka, Kanagawa (JP); Hiroaki Takeda, Kanagawa (JP)

Correspondence Address: MCDERMOTT WILL & EMERY LLP, 600 13TH STREET, NW, WASHINGTON, DC, 20005-3096, US

(21) Appl. No.: 11/979,115

(22) Filed: Oct. 31, 2007

(30) Foreign Application Priority Data
Nov. 6, 2006 (JP) P. 2006-300270
Aug. 23, 2007 (JP) P. 2007-217400

(51) Int. Cl. H04L 27/00; H03G 3/00

(52) U.S. Cl. 375/316; 381/104

(57) ABSTRACT

A broadcast receiving terminal having a calculating process unit operated at different clock frequencies in response to modes executes a mode switching method comprising the below-mentioned steps. The mode switching method is comprised of: a step for judging whether or not a mode switching instruction is issued while the calculating process unit is operated; a step for setting the calculating process unit to an idling status when the mode switching instruction is issued; and a step for releasing the idling status of the calculating process unit.

### BACKGROUND OF THE INVENTION

1. Field of the Invention

The present invention is related to a broadcast receiving terminal equipped with a calculating process unit operated in different clock frequencies in response to modes, a mode switching method performed by the broadcast receiving terminal, and a mode switching program executed in the broadcast receiving terminal.

2. Description of the Related Art

As one of the services as to the Japanese ground-based digital television broadcasting system, a so-called “1seg” (1 segment) service has been provided for portable telephones and mobile terminals. In the case that power supplies of broadcast receiving terminals capable of receiving television programs based upon the “1seg” service are batteries, it is desirable to realize low power consumption in view of driving times thereof. To this end, two operation modes have been prepared for broadcast receiving terminals: namely, in a normal mode, a function (will be referred to as “acoustic adding function” hereinafter) capable of realizing a superior sound quality is performed; and in a power saving mode, since the acoustic adding function is not executed, although a sound quality is deteriorated, as compared with that of the normal mode, power consumption is low. As indicated in FIG. 4, setting of an operation mode of a broadcast receiving terminal to any one of these two operation modes (namely, any one of normal mode and power saving mode) is carried out before viewing of a broadcast program is commenced.

The above-described broadcast receiving terminal contains a calculating process unit for performing data processing operations, control operations, and the like in order to reproduce pictures and sound. When the operation mode of the broadcast receiving terminal is set to the normal mode, the calculating process unit executes the acoustic adding function, whereas when the operation mode of the broadcast receiving terminal is set to the power saving mode, the calculating process unit does not execute the acoustic adding function. As a result, a process amount of the calculating process unit is small when the power saving mode is selected, as compared with a process amount thereof when the normal mode is selected. As a consequence, even when a clock frequency of the calculating in the power saving mode, there is no operational problem. In other words, when a power saving aspect is considered, if the calculating process unit is operated at a low clock frequency, then power consumption thereof is reduced, resulting in a better condition. Accordingly, when the power saving mode is selected, not only the acoustic adding function is not carried out, but also if clock frequencies containing an internal clock frequency and an external clock frequency are lowered, then power consumption of the broadcast receiving terminal can be considerably reduced.

It should be understood that when the clock frequencies are switched while the calculating process unit is under process operation, there are higher possibilities that software under execution in the calculating process unit, and operations of hardware containing the calculating process unit are brought in to unstable conditions. Also, since reproducing operation cannot be temporarily stopped while a broadcast program is viewed, the clock frequencies cannot be switched. As a consequence, such a broadcast receiving terminal capable of switching operation modes thereof even while a broadest program is viewed has been wanted.

### SUMMARY OF THE INVENTION

An object of the present invention is provide a broadcast receiving terminal capable of switching operation modes even while a broadcast program is viewed, a mode switching method which is executed by the above-described broadcast receiving terminal, and a mode switching program which is performed in the above-described broadcast receiving terminal.

The present invention is to provide a mode switching method featured by such a mode switching method which is performed by a broadcast receiving terminal having a calculating process unit operated at different clock frequencies in response to modes, comprising: a step for judging whether or not a mode switching instruction is issued during operation of the calculating process unit; a step for setting the calculating process unit to an idling status when the mode switching instruction is issued; a step for switching the operation mode of the broadcast receiving terminal to the instructed operation mode; and a step for releasing the idling status of the calculating process unit.

The above-described mode switching method is comprised of: a step by which when the mode switching instruction is issued, a sound volume adjusting unit contained in the broadcast receiving terminal is controlled so as to fade out, or mute sound outputted from the broadcast receiving terminal before the calculating process unit is set to the idling status; and a step for releasing fading-in of the sound, or muting of the sound, which are outputted from the broadcast receiving terminal after the idling status of the calculating process unit has been released.

In the above-described mode switching method, the broadcast receiving terminal is switched between a first mode during which the calculating process unit is operated at a first clock frequency, and a second mode during which the calculating process unit is operated at a second clock frequency.

In the above-described mode switching method, an audio processing unit contained in the broadcast receiving terminal is controlled so as to switch an execution and no execution of an additional function held by the sound processing unit.

In the above-described mode switching method, in the first mode, the additional function of the audio processing unit held by the broadcast receiving terminal is executed, whereas in the second mode, the additional function of the audio processing unit is not executed in the second mode.

The present invention is to provide a mode switching program featured by such a mode switching program which is executed by a broadcast receiving terminal having a calculating process unit operated at different clock frequencies in response to modes, in which the mode switching program causes a computer employed in the broadcast receiving terminal to realize: a function for judging whether or not a mode switching instruction is issued while the calculating process unit is performed; a function for setting the calculating process unit to an idling status when the mode switching instruction is issued; and a function for switching the operation mode of the broadcast receiving terminal to the instructed mode.

In the above-described mode switching program, when the mode switching instruction is issued, the mode switching program causes the computer to realize: a function by which a sound volume adjusting unit contained in the broadcast receiving terminal is controlled so as to fade out, or mute sound outputted from the broadcast receiving terminal before the calculating process unit is set to the idling status; and a function for releasing fading-in of the sound, or muting of the sound, which are outputted from the broadcast receiving terminal after the idling status of the calculating process unit has been released.

In the mode switching program, the broadcast receiving terminal is switched between a first mode during which the calculating process unit is operated at a first clock frequency, and a second mode during which the calculating process unit is operated at a second clock frequency.

In the mode switching program, an audio processing unit contained in the broadcast receiving terminal is controlled so as to switch an execution and no execution of an additional function held by the sound processing unit.

In the mode switching program, in the first mode, the additional function of the audio processing unit held by the broadcast receiving terminal is executed, whereas in the second mode, the additional function of the audio processing unit is not executed in the second mode.

The present invention is to provide a broadcast receiving terminal featured by such a broadcast receiving terminal having a calculating process unit operated at different clock frequencies in response to modes, comprising: a control unit which judges whether or not a mode switching instruction is issued while the calculating process unit is operated; which sets the calculating process unit to an idling status when the mode switching instruction is issued; which switches the operation mode of the calculating process unit to the instructed operation mode; and which releases the idling status of the calculating process unit.

In accordance with the mode switching method, the mode switching program, and the broadcast receiving terminal, which are related to the present invention, the operation modes can be switched even while broadcast programs are received.

### BRIEF DESCRIPTION OF THE DRAWINGS

FIG. 1 is a block diagram for indicating a broadcast receiving terminal of an embodiment mode of the present invention.

FIG. 2 is a block diagram for showing an audio processing unit of the broadcast receiving terminal.

FIG. 3 is a flow chart for representing a mode switching method of the present embodiment mode.

FIG. 4 is a flow chart for describing the conventional mode switching method.

### DESCRIPTION OF PREFERRED EMBODIMENTS

Referring now to drawings, a description is made of embodiment modes of the present invention. A broadcast receiving terminal of the below-mentioned embodiment mode is operable in correspondence with the television broadcasting system based upon the above-described so-called “1seg” service.

It should be understood that in a description of the present embodiment mode, it is assumed that respective process operations of the broadcast receiving terminal are carried out by executing only software. Alternatively, these respective process operations may be realized based upon hardware capable of performing process operations equivalent to the respective process steps, and also, software capable of controlling the above-described hardware. For instance, alternatively, a judging step may be realized by providing a judging unit which performs an equivalent process operation thereto; a setting step may be realized by providing hardware for detecting information used to judge a setting unit for performing an equivalent process operation, and a setting unit capable of performing a setting operation under control by the software. As a result, such process operations equivalent to the execution only by the software may be realized.

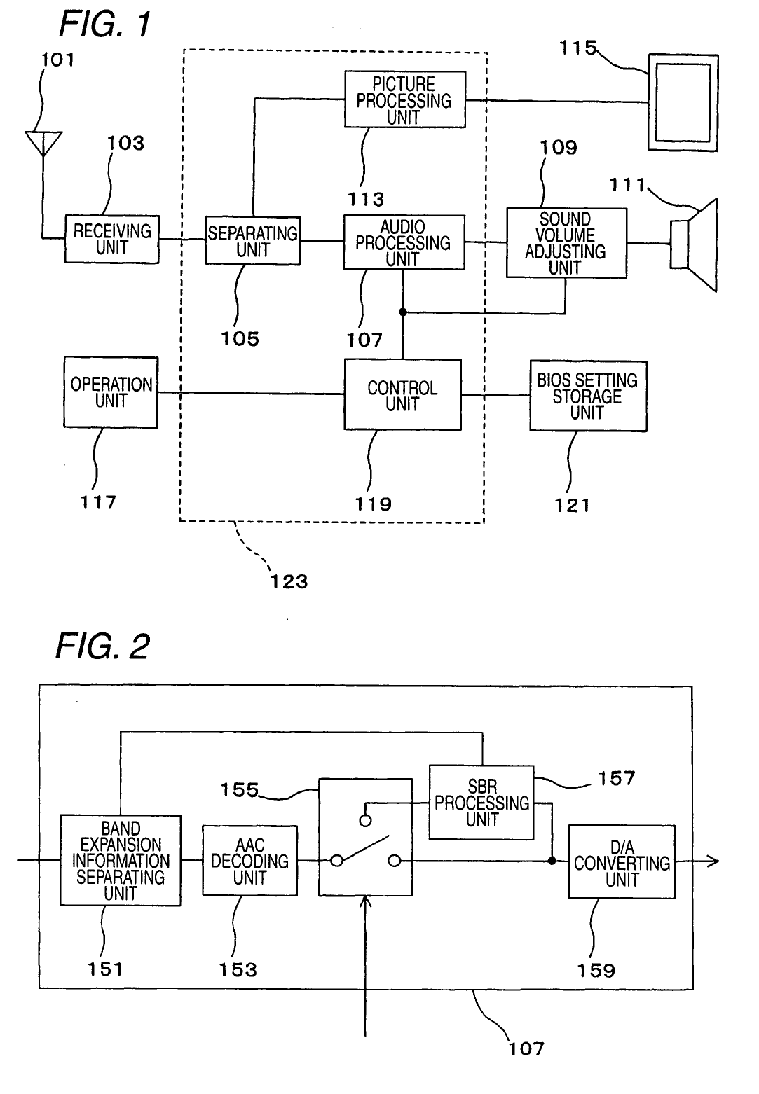

FIG. 1 is a block diagram for showing a broadcast receiving terminal according to an embodiment mode of the present invention. As shown in FIG. 1, the broadcast receiving terminal of the present embodiment mode is equipped with an antenna 101, a receiving unit 103, a separating unit 105, an audio processing unit 107, a sound volume adjusting unit 109, a speaker 111, a picture processing unit 113, a display 115, an operation unit 117, a control unit 119, and a BIOS setting storage unit 121. It should also be noted that the separating unit 105, the sound processing unit 107, the picture processing unit 113, and the control unit 119 may be alternatively realized by a calculating process apparatus such as a CPU which is operated by executing a program.

The antenna 101 receives digital broadcast electromagnetic waves. The receiving unit 103 processes the digital broadcast electromagnetic waves received by the antenna 101 so as to output a transport stream signal (TS). The separating unit 105 separates the transport stream signal into an audio elementary stream signal (AUDIO ES) and a video elementary stream signal (VIDEO ES), and then, inputs the audio elementary stream signal to the audio processing unit 107, and also, inputs the video elementary stream signal to the picture processing unit 113.

The audio processing unit 107 processes the data of the audio elementary stream signal. While the data of the audio elementary stream signal entered to the audio processing unit 107 corresponds to such a data compressed by an audio compression system called as “MPEG2 AAC+SBR”, the audio elementary stream signal data contains both audio coded data and band expansion information. The audio coded data corresponds to such a data compressed by an audio compression system called as AAC (Advanced Audio Coding). It should be understood that if audio data is compressed based upon the ACC system, then data of a high frequency component is deleted, and therefore, even when the ACC-compressed audio coded data is decoded, the high frequency band is not reproduced. The band expansion information corresponds to SBR (Spectral Band Replication: registered trademark) data which has compressed information indicative of a relative relationship between data of a low frequency component and a high frequency component which disappears when audio data is AC C-compressed.

FIG. 2 is a block diagram for representing an internal arrangement of the audio processing unit 107. As shown in FIG. 2, the audio processing unit 107 contains a band expansion information separating unit 151, an AAC decoding unit 153, a switching unit 155, an SBR processing unit 157, and a D/A converting unit 159. The band expansion information separating unit 151 separates the audio elementary stream signal into audio coded signal and band expansion information, and then, inputs the audio coded data to the AAC decoding unit 153, and also, inputs the band expansion information to the SBR processing unit 157. The AAC decoding unit 153 decodes the audio coded data so as to output low frequency band audio data (process operation by AAC decoding unit 153 will be referred to as “AAC processing operation” hereinafter). The SBR processing unit 157 predicts a high frequency audio band based upon the band expansion information and the low frequency band audio data so as to produce high frequency band audio data (process operation by SBR processing unit 157 will be referred to as “SBR processing operation” hereinafter). The D/A converting unit 159 D/A converts the audio data.

In the present embodiment mode, as audio reproducing modes of the broadcast receiving terminal, the below-mentioned two modes have been prepared; namely, in a normal mode, audio data produced based upon both low frequency band audio data and high frequency band audio data is reproduced; and in a power saving mode, audio data produced based upon only the low frequency band audio data is reproduced. The switching unit 155 switches the operation mode between the normal mode and the power saving mode in response to an instruction issued from the control unit 119. Under such a condition that the broadcast receiving terminal has been set to the normal mode, the low frequency band audio data outputted from the AAC decoding unit 153 is entered to the SBR processing unit 157. On the other hand, under such a condition that the broadcast receiving terminal has been set to the power saving mode, the low frequency band audio data outputted from the AAC decoding unit 153 is not entered to the SBR processing unit 157, but is entered to the D/A converting unit 159. As a result, the SBR process operation is not carried out when the power saving mode is selected. It should also be noted that the SBR process operation corresponds to the “acoustic adding function” capable of realizing a superior second quality. In the normal mode in which the acoustic adding function is executed, the SBR processing unit 157 is operated, whereas in the power saving mode in which the acoustic adding function is not executed, the SBR processing unit 157 is not operated, so that power consumption is small.

The sound volume adjusting unit 109 adjusts a level of an analog audio signal outputted from the audio processing unit 107. The sound volume adjusting unit 109 is controlled by the control unit 119, and has various functions, for example, a muting function, a fade out function, a fade in function, and the like. The speaker 111 outputs sound at an adjusted level in response to the analog audio signal.

The picture processing unit 113 performs such a process operation so as to decode the video elementary stream signal and to display the decoded video elementary stream signal on the display 115. The display 115 displays thereon a television picture.

The operation unit 117 corresponds to an input interface via which a user operates the broadcast receiving terminal. The user can selects either the normal mode or the power saving mode by employing the operation unit 117. The control unit 119 controls the respective structural elements in such a manner that the operation mode of the broadcast receiving terminal becomes a mode selected by operating the operation unit 117 by the user. In the present embodiment mode, when the control unit 119 performs a mode switching operation, the calculating process unit 123 containing the separating unit 105, the audio processing unit 107, the picture processing unit 113, and the control unit 119 is set to either an operating condition or an idling condition. In the operating condition, a control operation is not newly carried out from the software with respect to the hardware, whereas in the idling condition, both the software and the hardware do not perform the own status transitions in an autonomous manner. It should also be noted that when the calculating process operations 123 is transferred to the idling status, after the software has been brought into the idling status by an interrupt process operation, the hardware is brought into the idling status.

The BIOS setting storage unit 121 stores thereinto basic information related to clock frequencies and the like, which contain an internal clock and an external clock. The separating unit 105, the audio processing unit 107, the picture processing unit 113, and the control unit 119 are operated in response to the clock frequencies set to the BIOS setting storage unit 121. In the present embodiment mode, 2 sorts of clock frequencies can be set. The control unit 119 sets a high clock frequency “f_{H}” in the normal mode, and sets a low clock frequency “f_{L}” in the power saving mode.

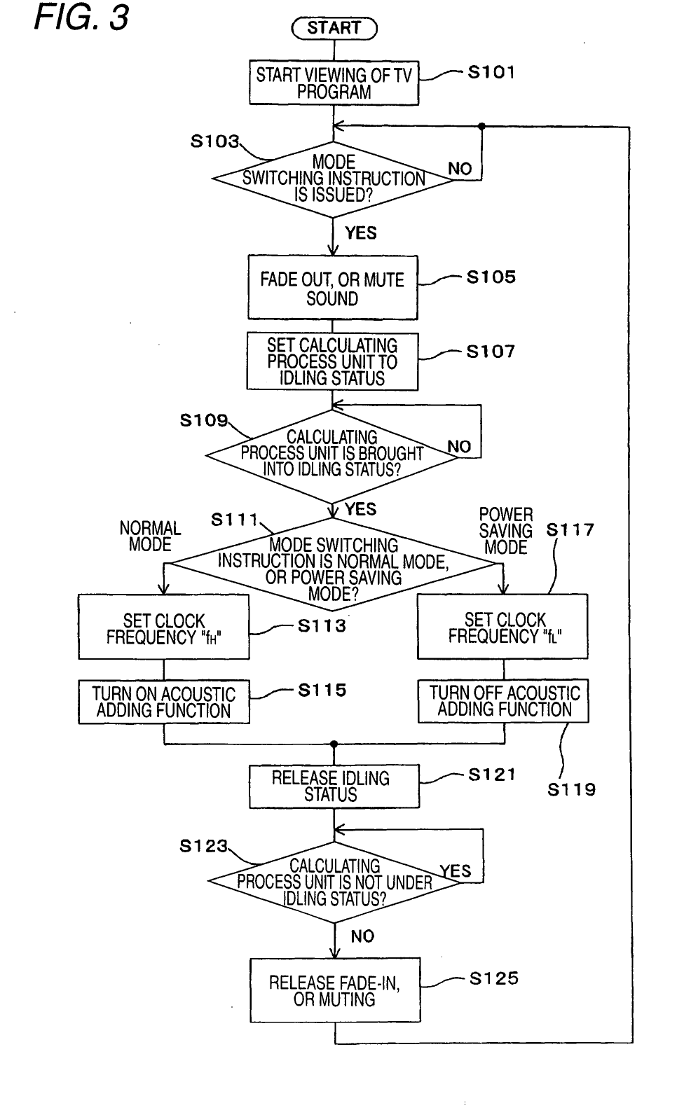

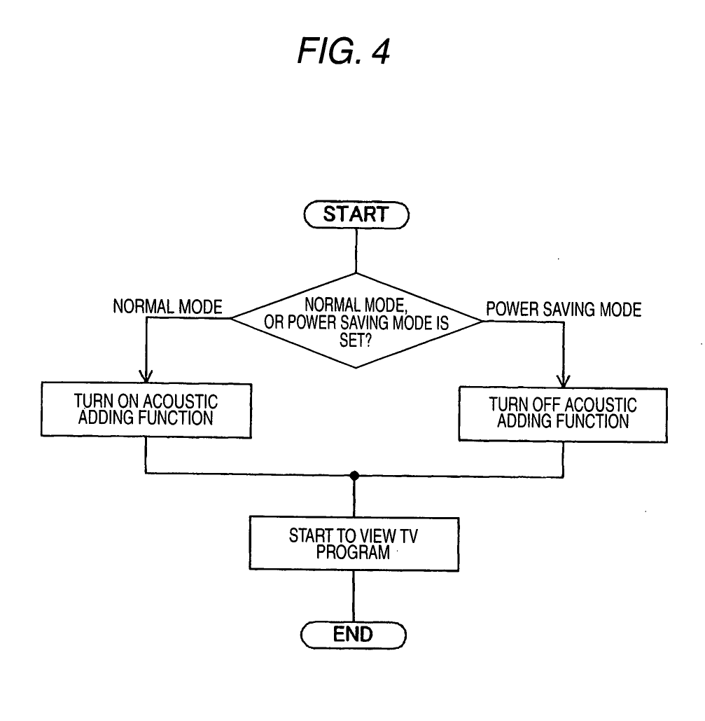

FIG. 3 is a flow chart for describing operations (mode switching method) of the broadcast receiving terminal according to the present embodiment mode. As indicated in FIG. 3, after viewing of a television broadcast program is commenced (step S101), the control unit 119 judges whether or not a mode switching instruction is issued (step S103). When the mode switching instruction is issued, the control unit 119 controls the sound volume adjusting unit 109 in order to fade out, or mute sound (step S105). Next, the control unit 119 sets the calculating process unit 123 to the idling status in the software manner and the hardware manner (step S107), while the calculating process unit 123 contains the separating unit 105, the audio processing unit 107, the picture processing unit 113, and the control unit 119.

After the control unit 119 confirms that the status of the calculating process unit 123 has been transferred to the idling status (step S109), the control unit 119 switches the present operation mode to the designated operation mode (step S111). In such a case that the normal mode has been designated, the control unit 119 sets the clock frequency “f_{H}” to the BIOS setting storage unit 121 (step S113), and controls the switching unit 155 of the audio processing unit 107 in order to perform the acoustic adding function (step S115). On the other hand, in such a case that the power saving mode has been designated, the control unit 119 sets the clock frequency “f_{L}” to the BIOS setting storage unit 121 (step S117), and controls the switching unit 155 of the audio processing unit 107 in order not to perform the acoustic adding function (step S119).

After the control unit 119 has performed the process operation defined in either the step S115 or the step S119, the control unit 119 releases the idling status of the calculating process unit 123 (step S121). The control unit confirms that the calculating process operation 123 is not under the idling status (step S123), and thereafter, controls the sound volume adjusting unit 109 so as to release the fade-in, or the muting of the sound (step S125).

As previously described, in accordance with the broadcast receiving terminal and the mode switching method of the present embodiment mode, the operation modes (namely, normal mode and power saving mode) can be switched even while the broadcast program is viewed. Also, the sound is faded out, or muted before the operation mode is switched. As a result, it is possible to prevent an occurrence of noisy sound produced when the operation mode is switched.

It should also be understood that in the present embodiment mode, the acoustic adding function has been set to be turned ON/OFF when the operation mode is switched. Alternatively, the acoustic adding function may be set to be turned ON/OFF when such a setting operation for changing power consumption is changed, for instance, an acoustic effect such as an equalizer is changed, a data path is switched, and the like. Also, although the present embodiment mode has exemplified the broadcast receiving terminal operable in response to the television broadcast program by the “1seg”, the present invention may be alternatively applied to a broadcast receiving terminal operable in response to a digital radio broadcast program.

The broadcast receiving terminal, according to the present invention, is useful as a terminal capable of receiving a broadcasting program and capable of switching the operation modes even while the broadcast program is viewed.

What is claimed is:

1. A mode switching method which is performed by a broadcast receiving terminal having a calculating process unit operated at different clock frequencies in response to modes, comprising:
a step for judging whether or not a mode switching instruction is issued during operation of said calculating process unit while the broadcast receiving terminal receives and views a broadcast program, or while the broadcast receiving terminal views a recorded/stored broadcast program;
a step for setting said calculating process unit to an idling status when said mode switching instruction is issued; and
a step for switching the operation mode of said broadcast receiving terminal to said instructed operation mode.

2. The mode switching method as claimed in claim 1, further comprising:
a step for releasing the idling status of said calculating process unit.

3. The mode switching method as claimed in claim 1, further comprising:
a step by which when said mode switching instruction is issued, a sound volume adjusting unit contained in said broadcast receiving terminal is controlled so as to fade out, or mute sound outputted from said broadcast receiving terminal before said calculating process unit is set to the idling status; and
a step for releasing fading-in of the sound, or muting of the sound, which are outputted from said broadcast receiving terminal after the idling status of said calculating process unit has been released.

4. The mode switching method as claimed in claim 1, wherein:
said broadcast receiving terminal is switched between a first mode during which said calculating process unit is operated at a first clock frequency, and a second mode during which said calculating process unit is operated at a second clock frequency.

5. The mode switching method as claimed in claim 1, wherein:
an audio processing unit contained in said broadcast receiving terminal is controlled so as to switch an execution and no execution of an additional function held by said sound processing unit.

6. The mode switching method as claimed in claim 4 wherein:
in said first mode, the additional function of the audio processing unit held by said broadcast receiving terminal is executed, whereas in said second mode, the additional function of said audio processing unit is not executed in said second mode.

7. A mode switching program product embodied on a computer readable medium which, when executed by a broadcast receiving terminal having a calculating process unit operated at different clock frequencies in response to modes, causes the broad cast receiving terminal to realize:
a function for judging whether or not a mode switching instruction is issued while said calculating process unit is performed;
a function for setting said calculating process unit to an idling status when said mode switching instruction is issued; and
a function for switching the operation mode of said broadcast receiving terminal to said instructed mode.

8. The mode switching program product as claimed in claim 7 wherein said mode switching program realizes:
a function for releasing the idling status of said calculating process unit.

9. The mode switching program product as claimed in claim 7, or claim 8 wherein when said mode switching instruction is issued,
said mode switching program causes said computer to realize:
a function by which a sound volume adjusting unit contained in said broadcast receiving terminal is controlled so as to fade out, or mute sound outputted from said broadcast receiving terminal before said calculating process unit is set to the idling status; and
a function for releasing fading-in of the sound, or muting of the sound, which are outputted from said broadcast receiving terminal after the idling status of said calculating process unit has been released.

10. The mode switching program as claimed in claim 7, wherein:
said broadcast receiving terminal is switched between a first mode during which said calculating process unit is operated at a first clock frequency, and a second mode during which said calculating process unit is operated at a second clock frequency.

11. The mode switching program as claimed in claim 7, wherein:
an audio processing unit contained in said broadcast receiving terminal is controlled so as to switch an execution and no execution of an additional function held by said sound processing unit.

12. The mode switching program as claimed in claim 10 wherein:
in said first mode, the additional function of the audio processing unit held by said broadcast receiving terminal is executed, whereas in said second mode, the additional function of said audio processing unit is not executed in said second mode.

13. A broadcast receiving terminal having a calculating process unit operated at different clock frequencies in response to modes, comprising:
a control unit which judges whether or not a mode switching instruction is issued while said calculating process unit is operated;
which sets said calculating process unit to an idling status when said mode switching instruction is issued;
which switches the operation mode of said calculating process unit to the instructed operation mode; and
which releases said idling status of the calculating process unit.

14. A broadcast receiving terminal, having a calculating process unit operated at different clock frequencies in response to modes, comprising:
a judging unit for judging whether or not a mode switching instruction is issued during operation of said calculating process unit while the broadcast receiving terminal receives and views a broadcast program, or while the broadcast receiving terminal views a recorded/stored broadcast program;
a setting unit for setting said calculating process unit to an idling status when said mode switching instruction is issued;
a switching unit for switching the operation mode of said broadcast receiving terminal to said instructed operation mode; and
a releasing unit for releasing the idling status of said calculating process unit, which can be found out from any one of a generation of an interrupt signal and an increase of a consumed current.

15. The broadcast receiving terminal as claimed in claim 14, further comprising:
a releasing unit for releasing the idling status of said calculating process unit.

16. The broadcast receiving terminal as claimed in claim 14, further comprising:
a sound volume adjusting unit contained in said broadcast receiving terminal, which is controlled so as to fade out, or mute sound outputted from said broadcast receiving terminal before said calculating process unit is set to an idling status when said mode switching instruction is issued; and
which releases either fading-in or muting of the sound outputted from said broadcast receiving terminal after the idling status of said calculating process unit has been released.

17. The broadcast receiving terminal as claimed in claim 14, wherein:
said broadcast receiving terminal is switched between a first mode during which said calculating process unit is operated at a first clock frequency, and a second mode during which said calculating process unit is operated at a second clock frequency.

18. The broadcast receiving terminal as claimed in claim 14, wherein:
an audio processing unit contained in said broadcast receiving terminal is controlled so as to switch an execution and no execution of an additional function held by said sound processing unit.

19. The broadcast receiving terminal as claimed in claim 17 wherein, in said first mode, the additional function of the audio processing unit held by said broadcast receiving terminal is executed, whereas in said second mode, the additional function of said audio processing unit is not executed in said second mode.
